(19) United States
(12) Patent Application Publication
(10) Pub. No.: US 2015/0263090 A1
(43) Pub. Date: Sep. 17, 2015

(54) SEMICONDUCTOR DEVICE

(71) Applicant: KABUSHIKI KAISHA TOSHIBA, Tokyo (JP)

(72) Inventor: Masahiro INOHARA, Fujisawa Kanagawa (JP)

(21) Appl. No.: 14/480,067

(22) Filed: Sep. 8, 2014

(30) Foreign Application Priority Data
Mar. 13, 2014 (JP) 2014-050789

(51) Int. Cl. H01L 29/06; H01L 29/205; H01L 27/088

(52) U.S. Cl. CPC H01L 29/0692; H01L 27/088; H01L 29/205

(57) ABSTRACT

According to one embodiment, a semiconductor device includes a silicon substrate, a first semiconductor element, a first semiconductor layer, and a second semiconductor element. The silicon substrate includes a first portion and a second portion. The first portion has a first face. The second portion has a second face. An angle between the first face and the second face is 125 degrees or more and 126 degrees or less. The first semiconductor element is provided at the first portion. The first semiconductor layer is provided on the second face. The second semiconductor element is provided at the first semiconductor layer.

### CROSS-REFERENCE TO RELATED APPLICATIONS

This application is based upon and claims the benefit of priority from the Japanese Patent Application No. 2014-050789, filed on Mar. 13, 2014; the entire contents of which are incorporated herein by reference.

### FIELD

Embodiments described herein relate generally to a semiconductor device.

### BACKGROUND

For example, a semiconductor element containing gallium nitride is provided on a (111) plane of a silicon substrate. On the other hand, the semiconductor element may be provided on a (100) plane of the silicon substrate. For example, there is also a semiconductor device obtained by stacking the semiconductor element formed on the (111) plane and the semiconductor element formed on the (100) plane. The semiconductor device is desired to make high performance and have stable characteristics.

### BRIEF DESCRIPTION OF THE DRAWINGS

FIGS. 1A to 1C are schematic views illustrating a semiconductor device according to an embodiment;

FIGS. 2A to 2D are schematic cross-sectional views illustrating a semiconductor device according to a variation of a first embodiment;

FIG. 3 is a perspective plan view illustrating the semiconductor device according to the first embodiment;

FIGS. 4A to 4E are schematic views illustrating a manufacturing process of the semiconductor device according to the first embodiment;

FIGS. 5A and 5B are schematic views illustrating a semiconductor device according to a second embodiment; and

FIG. 6 is a schematic view illustrating a semiconductor device according to a third embodiment.

### DETAILED DESCRIPTION

According to one embodiment, a semiconductor device includes a silicon substrate, a first semiconductor element, a first semiconductor layer, and a second semiconductor element. The silicon substrate includes a first portion and a second portion. The first portion has a first face. The second portion has a second face. An angle between the first face and the second face is 125 degrees or more and 126 degrees or less. The first semiconductor element is provided at the first portion. The first semiconductor layer is provided on the second face. The second semiconductor element is provided at the first semiconductor layer.

Various embodiments will be described hereinafter with reference to the accompanying drawings.

In addition, the drawings are illustrated schematically or conceptually, and thus relations between thicknesses and widths of the respective portions and ratios of sizes between the portions may not be necessarily depicted as actual dimensions. Further, even in a case where the same portions are depicted, the dimensions or the ratios thereof may be depicted differently from each other depending on the drawings.

In addition, in the specification and the drawings of the application, the same elements as those in a previously mentioned description relating to a previous drawing will be denoted with the same symbols and the detailed description thereof will appropriately not be made.

### First Embodiment

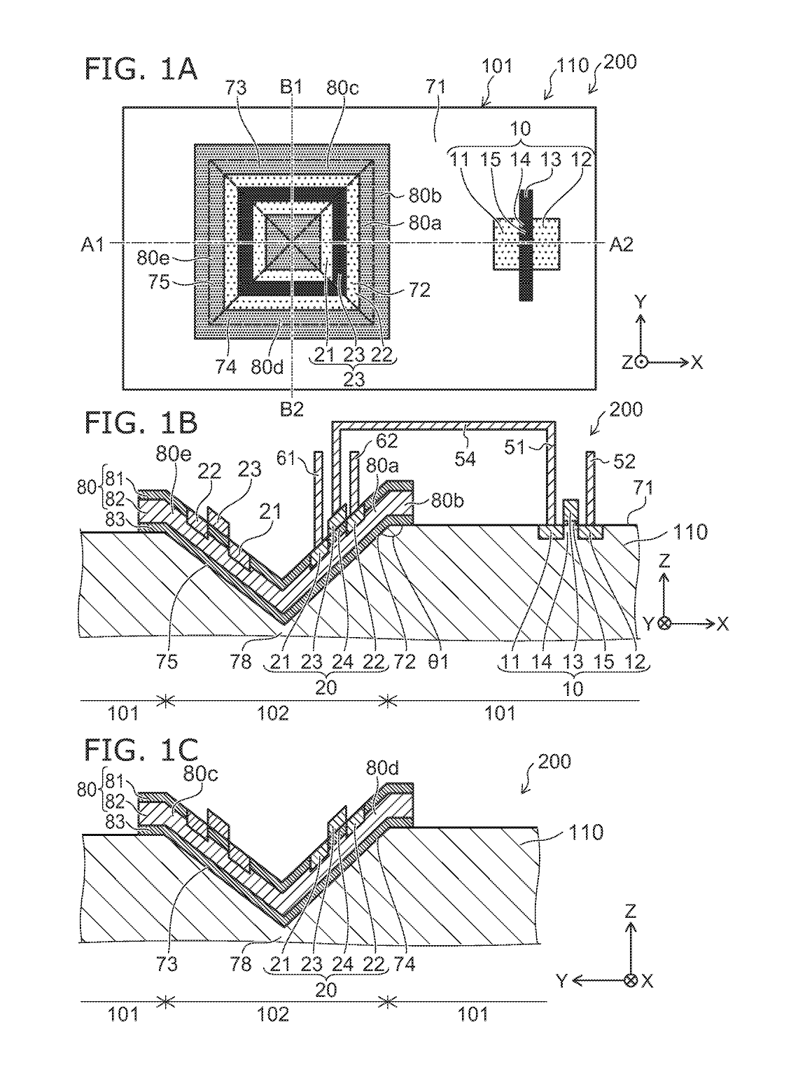

FIGS. 1A to 1C are schematic views illustrating a semiconductor device according to an embodiment.

FIG. 1A is a perspective plan view of a semiconductor device 200 according to the embodiment.

FIG. 1B is a schematic cross-sectional view taken along line A1-A2 of FIG. 1A.

FIG. 1C is a schematic cross-sectional view taken along line B1-B2 of FIG. 1B.

In FIGS. 1A to 1C, some parts of components are not illustrated for the convenience of visibility.

As illustrated in FIGS. 1A to 1C, the semiconductor device 200 according to the embodiment includes a silicon substrate 110, a first semiconductor layer 80, a first semiconductor element 10, and a second semiconductor element 20.

The silicon substrate 110 includes a first portion 101 and a second portion 102. The first portion 101 includes a first face 71. The second portion 102 includes a second face 72. In the example, the second portion 102 further includes a third face 73, a fourth face 74, and a fifth face 75.

The silicon substrate 110 contains silicon (Si). The first face 71, for example, is a silicon (100) plane. The second face 72, for example, is a silicon (111) plane. The third face 73, the fourth face 74, and the fifth face 75 are silicon (111) planes.

The second to fifth faces 72, 73, 74, and 75, for example, are faces which are provided to be continuous to the first face 71. An angle (a first angle θ1) formed between the first face 71 and each of the second to fifth faces 72, 73, 74, and 75, for example, is 125 degrees or more and 126 degrees or less. An angle formed between the first face 71 and each of the second to fifth faces 72, 73, 74, and 75, for example, is 125.26 degrees.

One direction perpendicular to the first face 71 will be assumed as a Z-axis direction. One direction perpendicular to the Z-axis direction will be assumed as an X-axis direction. A direction perpendicular to the X-axis direction and perpendicular to the Z-axis direction will be assumed as a Y-axis direction.

In the example, the silicon substrate 110 is extended in an X-Y plane.

The third face 73 and the fourth face 74 each are faces adjacent to the second face 72. For example, the third face 73 is a face which shares a side with the second face 72, and the fourth face 74 is a face which shares another side with the second face 72.

The fifth face 75 is a face which is adjacent to the third face 73 and the fourth face 74. For example, the fifth face 75 is a face which shares a side with each of the third face 73 and the fourth face 74.

For example, the second to fifth faces 72 to 75 are the silicon (111) planes which are formed on the silicon substrate having the (100) plane through crystal anisotropic etching. As illustrated in FIGS. 1B and 1C, the second to fifth faces 72 to 75 are wedge-shaped slopes in cross-sectional view.

The second portion 102 includes an intersecting portion 78. The intersecting portion 78 is a portion where the second face 72, the third face 73, the fourth face 74, and the fifth face 75 intersect with each other. The intersecting portion 78, for example, corresponds to the center region of the second portion 102 when projected onto the X-Y plane.

The first semiconductor element 10 is provided in the first portion 101 having the first face 71. The first semiconductor element 10, for example, includes a first drain region 11, a first source region 12, a gate electrode 13 (a first gate electrode), a channel region 14 (a first channel region), and a gate insulating film 15 (a first gate insulating film). The first semiconductor element 10, for example, is a MOSFET.

The first drain region 11 is provided in the first portion 101. The first source region 12 is provided in the first portion 101, and separated from the first drain region 11. The first drain region 11, for example, is drawn alongside of the first source region in the X-Y plane.

Each of the first drain region 11 and the first source region 12, for example, is a region which includes a part of the first face 71. In other words, the first drain region 11 and the first source region 12 are provided on a side near the surface of the silicon substrate 110.

The first channel region 14 is provided between the first drain region 11 and the first source region 12. The gate insulating film 15 is provided on the first channel region 14. The gate electrode 13 is provided on the gate insulating film 15.

The first drain region 11 contains a first conductivity type (for example, n-type) of impurity. For example, an impurity concentration in the first drain region 11 is higher than that in the silicon substrate 110.

The first source region 12 contains the first conductive type of impurity similarly to the first drain region 11. For example, an impurity concentration in the first source region 12 is higher than that in the silicon substrate 110.

In the embodiment, the first drain region 11 and the first source region 12 may contain a second conductivity type (for example, p-type) of impurity. As the n-type impurity, for example, phosphorus (P) or arsenic (As) is used. As the p-type impurity, for example, boron (B) is used.

For the gate electrode 13, for example, polysilicon is used. For the gate insulating film 15, for example, a silicon oxide or a silicon oxynitride is used.

For example, the first semiconductor element 10 further includes a first drain electrode 51 and a first source electrode 52. The first drain electrode 51 is electrically connected to the first drain region 11. The first source electrode 52 is electrically connected to the first source region 12.

The first semiconductor layer 80, for example, is provided on the second portion 102. The first semiconductor layer 80 includes a first region 80a. At least a part of the first region 80a is provided on the second face 72.

The first semiconductor layer 80, for example, contains AlₓGa₁₋ₓN (0≦x<1). The first semiconductor layer 80, for example, includes a first layer 81 and a second layer 82. The second layer 82 is provided between the first layer 81 and the second face 72. The first layer 81, for example, contains Alₓ₁Ga₁₋ₓ₁N (0<x1<1). The second layer 82, for example, contains Alₓ₂Ga₁₋ₓ₂N (0≦x2<x1). The second layer 82, for example, is a GaN layer. Further, the second layer 82, for example, is not doped. The second layer 82, for example, does not contain any impurity. A composition ratio of Al in the first layer 81, for example, is higher than that in the second layer 82. The first layer 81, for example, is an AlGaN layer. For example, the second layer 82 may be the AlGaN layer, and the first layer 81 may be an AlGaN layer having a composition ratio of Al higher than that in the second layer 82.

For example, a foundation layer 83 is provided between the silicon substrate 110 and the first semiconductor layer 80. For example, the foundation layer 83 is provided between the first semiconductor layer 80 and the second face 72. The foundation layer 83, for example, includes a nitride semiconductor. The foundation layer 83, for example, contains AlₐGa₁₋ₐN (0≦a≦1). The foundation layer 83, for example, includes a plurality of nitride semiconductors. The foundation layer 83, for example, includes a plurality of AlN layers, a plurality of AlGaN layers, and a plurality of GaN layers. These layers, for example, are repeatedly stacked in order of the AlN layer, the AlGaN layer, and the GaN layer in a stacking direction of the silicon substrate 110 and the foundation layer 83. In other words, the foundation layer includes a plurality stacked layers, each of the stacked layers includes an AlN layer, an AlGaN layer and a GaN layer. In other words, the foundation layer 83, for example, is a superlattice layer. The foundation layer 83 is not limited thereto, and, for example, may be a stacked film which includes a plurality of AlGaN layers, each of which is changed in a composition ratio of Al between AlN and GaN in a stepped manner. The foundation layer 83, for example, may have one layer (a so-called inclined layer) of which the composition ratio of Al is continuously changed as it goes from AlN to GaN in a direction perpendicular to the second face 72. In addition, the foundation layer 83 is provided as needed, and may not be provided.

In the example, the first semiconductor layer 80 further includes a second region 80b, a third region 80c, a fourth region 80d, and a fifth region 80e.

The second region 80b is provided on the first face 71. The second region 80b is provided to be continuous to the first region 80a.

The third region 80c is provided on the third face 73. The third region 80c is provided to be continuous to the first region 80a and the second region 80b.

Further, the fourth region 80d is provided on the fourth face 74. The fifth region 80e is provided on the fifth face 75. The first to fifth regions 80a to 80e are provided to be continuous to each other.

The second semiconductor element 20 is provided in the first semiconductor layer 80. The second semiconductor element 20, for example, includes a second drain region 21, a second source region 22, a gate electrode 23 (a second gate electrode), and a channel region 24 (a second channel region). The second semiconductor element 20, for example, is a high electron mobility transistor (HEMT).

The second drain region 21 is provided in the first semiconductor layer 80. In the example, the second drain region 21 is provided to be continuous to the first region 80a, the third region 80c, the fourth region 80d, and the fifth region 80e. For example, the second drain region 21 is provided to surround the intersecting portion 78 when projected onto the X-Y plane.

The second source region 22 is provided in the first semiconductor layer 80, and separated from the second drain region 21. In the example, the second source region 22 is provided to be continuous to the first region 80a, the third region 80c, the fourth region 80d, and the fifth region 80e. For example, the second source region 22 is provided to surround the second drain region 21.

In the embodiment, a positional relation between the drain region and the source region may be reversed.

The second channel region 24 is provided between the second drain region 21 and the second source region 22. The gate electrode 23 is provided on the second channel region 24. The gate electrode 23 is provided to surround the second drain region 21 when projected onto the X-Y plane. In the embodiment, the gate insulating film may be provided between the second channel region 24 and the gate electrode 23.

The second semiconductor element 20 further includes a second drain electrode 61 and a second source electrode 62. The second drain electrode 61 is electrically connected to the second drain region 21. The second source electrode 62 is electrically connected to the second source region 22.

As described above, the composition ratio of Al in the first layer 81 is higher than the composition ratio of Al in the second layer 82. In other words, a lattice constant of the first layer 81 is smaller than that of the second layer 82. Thus, distortion is caused in the first layer 81, and piezoelectric polarization is generated in the first layer 81 by a piezoelectric effect. Thereby, a two-dimensional electron gas is formed in the second layer 82 near a boundary with the first layer 81.

For example, the concentration of the two-dimensional electron gas under the gate electrode 23 is increased or decreased by controlling a voltage applied to the gate electrode 23. Thereby, an electric current flowing between the second drain region 21 and the second source region 22 is controlled.

In the example, the semiconductor device 200 further includes an interconnection 54. For example, the interconnection 54 electrically connects the gate electrode 23 and the first drain electrode 51. For example, the second semiconductor element is used as a power transistor, and the first semiconductor element 10 is used as a driver of the second semiconductor element 20. In this way, on one substrate, there can be obtained the semiconductor device in which semiconductor elements formed in the (100) plane and semiconductor elements formed in the (111) plane are mixed.

As described above, in the semiconductor device 200 according to the embodiment, the (100) plane and the (111) plane are provided on one silicon substrate. The semiconductor elements are formed in each of the (100) plane and the (111) plane. For example, a MOSFET is formed in the (100) plane, and a HEMT which contains GaN/AlGaN is formed in the (111) plane. Thereby, by mixing the HEMT and the MOSFET, it is possible to obtain the semiconductor device which makes high performance and has stable characteristics.

In a case where a semiconductor element including GaN is formed on the silicon substrate, a GaN layer is deposited on the silicon substrate. The deposition of a GaN layer is desirably performed on the (111) plane. In a case where the deposition of a GaN layer is performed on the (100) plane, a silicon lattice and a GaN lattice may be mismatched with each other, thereby causing degradation in film quality of the GaN layer. In this way, the degradation in characteristics of the semiconductor element may be caused.

Further, the MOSFET is desired to be formed on the silicon (100) plane. For example, a silicon oxide film which is formed on the (111) plane by thermal oxidation has a high dangling bond density in a boundary with silicon compared to a silicon oxide film which is formed on the (100) plane by thermal oxidation.

Thereby, in a case where the silicon oxide film formed on the (111) plane by the thermal oxidation is used, carriers are scattered to make the mobility largely degraded. Further, when hydrogen atoms that have terminated the dangling bond leave, it may cause a large variation in characteristics of the MOSFET.

On the contrary, in the embodiment, the semiconductor element is formed in each of the (100) plane and the (111) plane. Thereby, it is possible to obtain the semiconductor device which makes high performance and has stable characteristics.

For example, in the embodiment, the semiconductor elements can be formed on one substrate compared to a method in which a substrate having the (100) plane and another substrate having the (111) plane are both used. Thereby, it is possible to improve a production efficiency of the semiconductor devices. Further, it is possible to suppress production costs and improve the production efficiency compared to another method in which the semiconductor elements are formed using an SOI substrate.

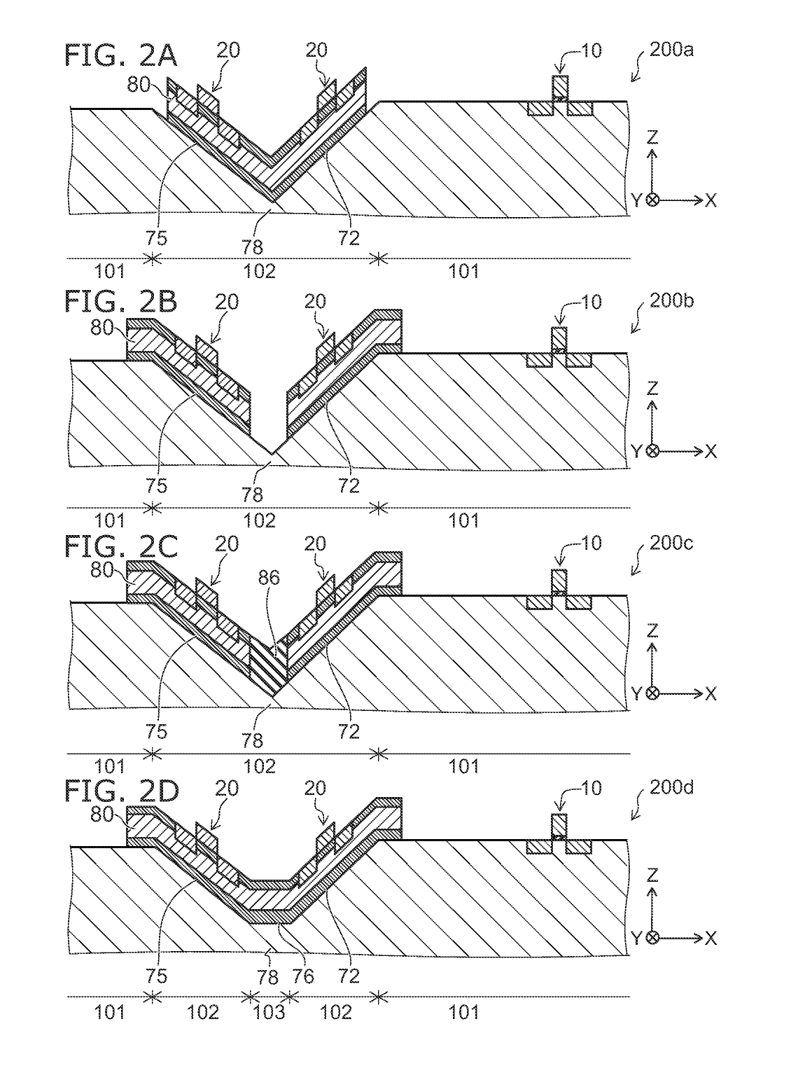

FIGS. 2A to 2D are schematic cross-sectional views taken along line A1-A2 of FIG. 1A, which illustrate a semiconductor device according to a variation of a first embodiment. FIGS. 2A to 2D illustrate a part of the semiconductor device. In semiconductor devices 200a to 200c illustrated in FIGS. 2A to 2D, the same configurations as those described for the semiconductor device 200 will be denoted with the same symbols, and the descriptions thereof will not be made.

As illustrated in FIG. 2A, in the semiconductor device 200a, the first semiconductor layer 80 is not provided on the first portion 101. In other words, the first semiconductor layer 80 may not include the second region 80b illustrated in FIG. 1B. In the semiconductor device 200a, the silicon (100) plane can be widely used compared to the semiconductor device 200.

Further, in the semiconductor device 200, the silicon (111) plane can be widely used compared to the semiconductor device 200a.

The end portion of the first semiconductor layer 80 in the semiconductor device 200a, for example, forms an acute angle, but the end portion of the first semiconductor layer 80 in the semiconductor device 200 forms about 90 degrees. Thereby, the semiconductor device 200 is improved in reliability.

As illustrated in FIG. 2B, in the semiconductor device 200b, the first semiconductor layer 80 is not provided on the intersecting portion 78. For example, the intersecting portion 78 and the first semiconductor layer 80 are not overlapped with each other when projected onto the X-Y plane. The first semiconductor layer 80 is not provided in the center region of a portion surrounded by the second drain region 21 when projected onto the X-Y plane.

For example, in a case where AlₓGa₁₋ₓN (0≦x<1) is deposited on the intersecting portion 78, the flatness of the substrate may be lowered in the intersecting portion 78 and cause the film quality to be degraded. For example, a degraded film quality portion of the first semiconductor layer 80 may cause the semiconductor element to be degraded in characteristics such that a leakage current is increased. As illustrated in FIG. 2B, it is possible to obtain the semiconductor element which has stable characteristics by removing the degraded film quality portion of AlₓGa₁₋ₓN (0≦x<1).

As illustrated in FIG. 2C, for example, before the deposition of AlₓGa₁₋ₓN (0≦x<1), an insulating film 86 such as the silicon oxide film may be provided in a region on the intersecting portion 78. Thereby, in a process of deposing AlₓGa₁₋ₓN (0≦x<1), AlₓGa₁₋ₓN (0≦x<1) is not formed in a region on the intersecting portion 78, so that it is possible to suppress the degradation in film quality of AlₓGa₁₋ₓN (0≦x<1).

As illustrated in FIG. 2D, the silicon substrate 110 of the semiconductor device 200d further includes a third portion 103. The third portion 103 is separated from the first portion 101. The second portion 102 is provided between the first portion 101 and the third portion 103. The third portion 103 is surrounded by the second portion 102 when projected onto the X-Y plane. The second portion 102 is provided around the third portion when projected onto the X-Y plane. The third portion 103 has a sixth face 76. The sixth face 76 is separated from the first face 71. For example, the sixth face 76 is substantially parallel to the first face 71. The sixth face 76, for example, is the silicon (100) plane. The sixth face 76, for example, is in contact with each of the second to fifth faces 72 to 75 when projected onto the X-Y plane.

The sixth face 76, for example, can be obtained by adjusting a time period or the like of the crystal anisotropic etching of the substrate in a manufacturing process, which will be described later.

The semiconductor device 200d has a flat face (the sixth face 76) in a portion corresponding to the intersecting portion 78 in the X-Y plane. With the flat face, it is possible to suppress the degradation in film quality in the case of the deposition of AlₓGa₁₋ₓN (0≦x<1).

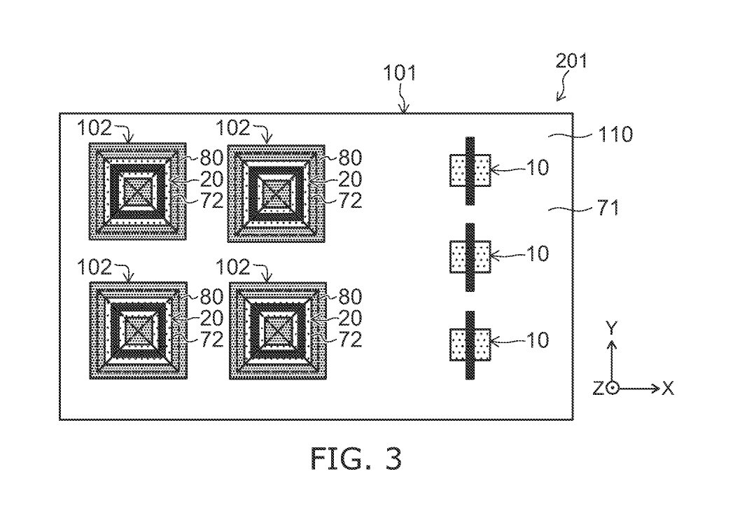

FIG. 3 is a perspective plan view illustrating the semiconductor device according to the first embodiment.

As illustrated in FIG. 3, a semiconductor device 201 includes the silicon substrate 110, a plurality of first semiconductor layers 80, a plurality of first semiconductor elements 10, and a plurality of second semiconductor elements 20.

The silicon substrate 110 includes the first portion 101 and a plurality of second portions 102. Each of the plurality of second portions 102 has the second face 72. The first semiconductor layer 80 is provided on each of the plurality of second faces 72. The second semiconductor element 20 is provided in each of the plurality of first semiconductor layers 80. In the example, four second semiconductor elements 20 are provided, but the number of second semiconductor elements 20 is arbitrary in the embodiment. The plurality of first semiconductor elements 10 are provided in the first portion 101. In the example, three first semiconductor elements 10 are provided, but the number of first semiconductor elements 10 is arbitrary in the embodiment.

For example, each of the plurality of first semiconductor elements 10 and each of the plurality of second semiconductor elements 20 are electrically connected to each other through an interconnection. Thereby, a circuit using these semiconductor elements can be formed on one substrate. In the embodiment, the arrangement of the plurality of first semiconductor elements 10, the arrangement of the plurality of second semiconductor elements 20, and a pattern of the interconnections between the semiconductor elements are arbitrary. In this way, the plurality of semiconductor elements may be formed on one substrate. Thereby, it is possible to obtain the semiconductor device which makes high performance and has stable characteristics.

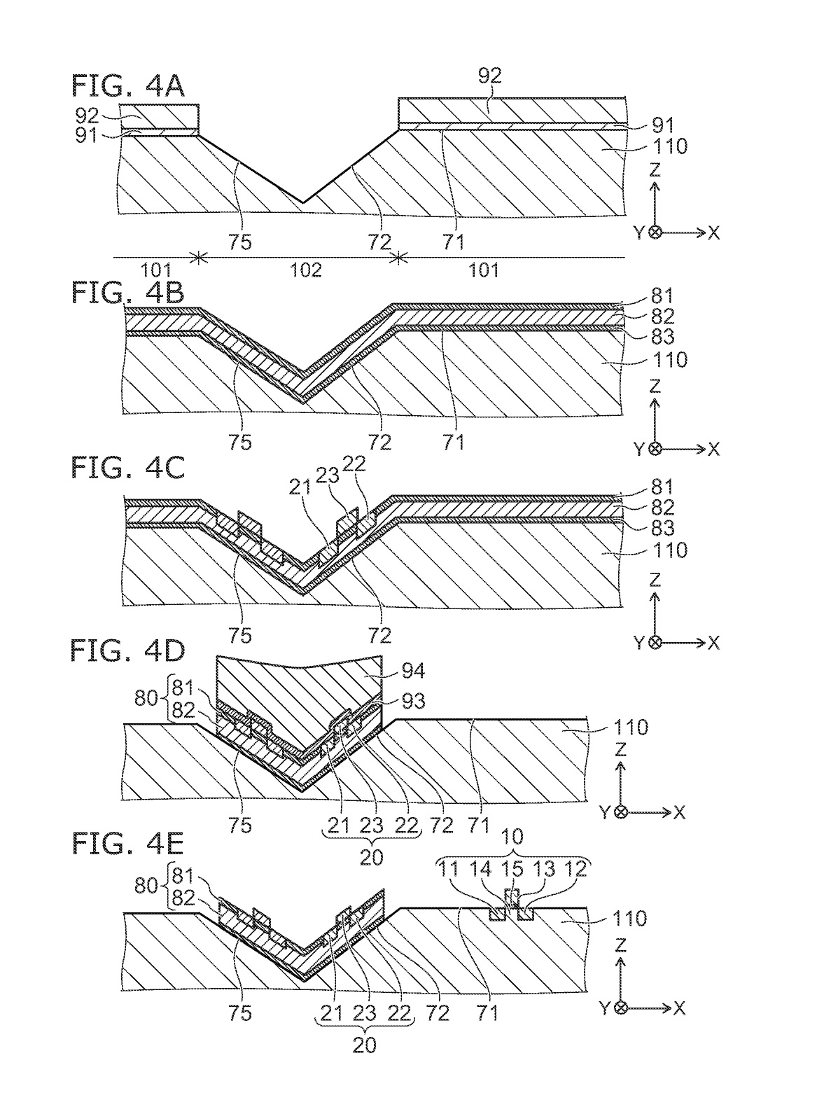

FIGS. 4A to 4E are schematic views illustrating a manufacturing process of the semiconductor device according to the first embodiment.

As illustrated in FIG. 4A, the silicon substrate 110 having the (100) plane is prepared.

For example, an oxide film 91 is formed on the silicon substrate 110 by a chemical vapor deposition (CVD) method. Thereafter, a resist 92 is formed on the oxide film 91. For example, a pattern is formed in the resist 92 using photolithography. A part of the oxide film 91 is peeled off using the resist 92 as a mask to make a part of the silicon substrate exposed. The exposed portion is subjected to the crystal anisotropic etching. Thereby, the silicon (111) plane (the second to fifth faces 72 to 75) is formed.

In the crystal anisotropic etching, for example, potassium hydroxide (KOH), tetra methyl ammonium hydroxide (TMAH), ethylene diaminepyrocatechol (EDP), hydrazine hydrate (N₂H₄.H₂O), or the like can be used. In addition, for example, a flat portion of the third portion 103 illustrated in FIG. 2D can be formed in the crystal anisotropic etching by adjusting an etching amount.

As illustrated in FIG. 4B, after the resist 92 and the oxide film 91 are peeled off, the foundation layer 83 (a lattice mismatch relaxation layer or a buffer layer) is deposited on the silicon substrate 110. The second layer 82 (for example, the GaN layer) is deposited on the foundation layer 83. The first layer 81 (for example, the AlGaN layer) is deposited on the second layer 82.

As illustrated in FIG. 4C, the second drain region 21, the second source region 22, and the gate electrode 23 are further formed. Thereby, a HEMT is formed. The gate insulating film may be formed below the gate electrode 23. The second drain region 21 and the second source region 22, for example, may be formed using an ion implantation method.

For example, the ion implantation method is performed from a direction perpendicular to the first face 71. Thereby, for example, the first semiconductor layers 80 formed on the second to fifth faces 72 to 75 can be simultaneously subjected to the ion implantation method. At this time, the second drain region 21 and the second source region 22 are formed asymmetrically to the gate electrode 23. The impurity is asymmetrically distributed. For example, at the time of driving the semiconductor element, an electric field is alleviated in the drain region compared to the source region due to the asymmetry of the impurity. Thereby, for example, a high breakdown voltage semiconductor element can be obtained. In addition, in the embodiment, a mask such as the resist is appropriately formed on each of the second to fifth faces 72 to 75 and a tilt angle is set, and then the ion implantation method may be performed.

As illustrated in FIG. 4D, for example, an oxide film 93 is formed on the second semiconductor element 20 by a CVD method. Then, a resist 94 is formed on the oxide film 93. For example, a pattern is formed on the resist 94 using photolithography. Some parts of the oxide film 93, the first layer 81, the second layer 82, and the foundation layer 83 are removed using the resist 94 as a mask to make the silicon (100) plane (the first face 71) exposed.

As illustrated in FIG. 4E, the first semiconductor element 10 (MOSFET) is formed in the first portion having the exposed first face 71. In the example, the second semiconductor element 20 is formed before the first semiconductor element 10 is formed. Before the second semiconductor element 20 is formed, the first semiconductor element 10 may be formed. For example, the first layer 81 and the second layer 82 may be deposited at a high temperature in some cases, so that it is desired to form the second semiconductor element 20 earlier.

### Second Embodiment

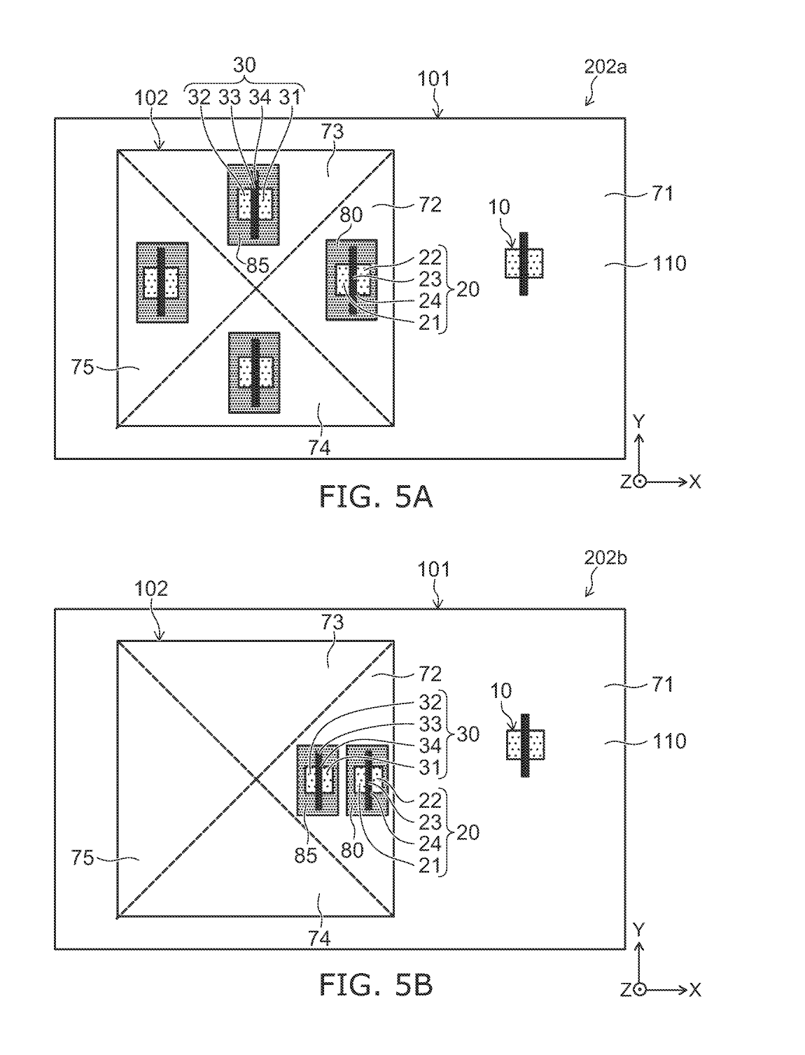

FIGS. 5A and 5B are schematic views illustrating a semiconductor device according to a second embodiment.

FIG. 5A is a perspective plan view illustrating a semiconductor device 202a according to the second embodiment.

FIG. 5B is a perspective plan view of a semiconductor device 202b according to the second embodiment.

Even in the semiconductor device 202a and the semiconductor device 202b, the silicon substrate 110, the first semiconductor layer 80, the first semiconductor element 10, and the second semiconductor element 20 are provided. In this regard, the same configurations as those described in the first embodiment will be denoted with the same symbols, and the descriptions thereof will not be made.

The semiconductor device 202a and the semiconductor device 202b further include a second semiconductor layer 85 and a third semiconductor element 30.

As illustrated in FIG. 5A, in the semiconductor device 202a, the second semiconductor layer 85, for example, is provided on the third face 73 through the foundation layer. The second semiconductor layer 85 is separated from the first semiconductor layer 80. The second semiconductor layer 85 can be applied with the same configuration as that of the first semiconductor layer 80.

The third semiconductor element 30 is provided in the second semiconductor layer 85. The third semiconductor element 30 includes a third drain region 31, a third source region 32, a gate electrode 33 (a third gate electrode), a channel region 34, and the like. The third semiconductor element 30, for example, is a HEMT. The third semiconductor element 30, for example, can be applied with the same configuration as that of the second semiconductor element 20.

As illustrated in FIG. 5B, in the semiconductor device 202b, the second semiconductor layer 85 is provided on the second face 72. The second semiconductor layer 85 is separated from the first semiconductor layer 80. The third semiconductor element 30 is provided in the second semiconductor layer 85.

In this way, a plurality of semiconductor layers are provided on the second portion 102, and a semiconductor element may be provided in each of the semiconductor layers. Further, the plurality of semiconductor elements may be provided in one semiconductor layer. The second semiconductor layer 85 may be provided in the fourth face 74 or the fifth face 75.

### Third Embodiment

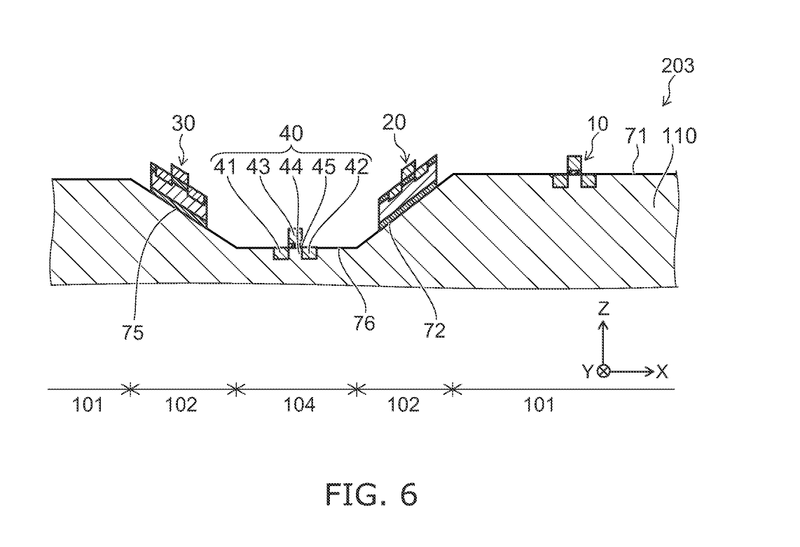

FIG. 6 is a schematic view illustrating a semiconductor device according to a third embodiment.

As illustrated in FIG. 6, even in a semiconductor device 203, the silicon substrate 110, the first semiconductor layer 80, the second semiconductor layer 85, the first semiconductor element 10, the second semiconductor element 20, and the third semiconductor element 30 are provided. In this regard, the same configurations as those described about the semiconductor device 202 will be denoted with the same symbols, and the descriptions thereof will not be made.

The semiconductor device 203 further includes a fourth semiconductor element 40. Further, the silicon substrate 110 further includes a fourth portion 104. The fourth semiconductor element 40 is provided in the fourth portion 104.

The fourth semiconductor element is provided on a region of the fourth portion 104, and includes a fourth drain region 41, a fourth source region 42, a gate electrode 43 (a fourth gate electrode), a channel region 44 (a fourth channel region), and a gate insulating film 45. The fourth semiconductor element 40, for example, is a MOSFET.

The fourth drain region 41 is separated from the fourth source region 42. The fourth drain region 41, for example, is drawn alongside of the fourth source region 42 in the X-Y plane.

The fourth channel region 44 is provided between the fourth drain region 41 and the fourth source region 42. The gate insulating film 45 is provided on the fourth channel region 44. The gate electrode 43 is provided on the gate insulating film 45.

In the embodiment, as described above, the plurality of (111) planes and the plurality of (100) planes are formed in the silicon substrate 110, and a semiconductor element may be formed on each of the planes.

According to the embodiment, the semiconductor device which makes high performance and has stable characteristics can be provided. In the embodiment, the description has been made about the HEMT using GaN/AlGaN, but the invention is not limited thereto. For example, the advantages of the embodiments can be obtained even using a HEMT configured of a GaAs-based semiconductor, an InP-based semiconductor, a SiGe-based semiconductor, or the like. Further, in the semiconductor device described above, one semiconductor element is formed on one semiconductor layer, but the embodiment is not limited thereto. For example, a plurality of semiconductor elements (HEMTs) may be provided on the first semiconductor layer 80.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hitherto, the embodiments of the invention have been described with reference to the specific examples. However, the embodiments of the invention are not limited to these specific examples. For example, a person skilled in the art can similarly implement the invention by selecting the specific configurations of the respective elements such as the substrate, the first and second semiconductor layers, the first to fourth semiconductor elements, the first to sixth faces, the source region, the drain region, the channel region, the gate insulating film, and the gate electrode from among a known scope. As long as the similar advantages can be obtained, it will be considered as falling within the scope of the invention.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a silicon substrate including
a first portion having a first face, and
a second portion having a second face, an angle between the first face and the second face being 125 degrees or more and 126 degrees or less;
a first semiconductor element provided at the first portion;
a first semiconductor layer provided on the second face; and
a second semiconductor element provided at the first semiconductor layer.

2. The device according to claim 1, wherein
the first semiconductor layer includes Alₓ₁Ga₁₋ₓ₁N (0≦x1<1).

3. The device according to claim 1, wherein
the first face is a (100) plane of silicon, and
the second face is a (111) plane of silicon.

4. The device according to claim 1, wherein
the first semiconductor layer includes a first layer and a second layer provided on the first layer,
the first semiconductor layer includes an impurity,
a concentration of the impurity in the second layer is high than a concentration of the impurity in the first layer.

5. The device according to claim 1, further comprising
a foundation layer provided between the first semiconductor layer and the second face.

6. The device according to claim 5, wherein
the foundation layer includes Alₓ₂Ga₁₋ₓ₂N (0≦x2≦1).

7. The device according to claim 5, wherein
the foundation layer includes a plurality of stacked layers,
each of the stacked layers includes an AlN layer, an AlGaN layer and a GaN layer.

8. The device according to claim 6, wherein
a composition ratio of Al in the foundation layer is continuously changed in a direction perpendicular to the second face.

9. The device according to claim 1, wherein
the first portion includes a first part, a second part, and a third part provided between the first part and the second part,
the first semiconductor element includes
a first source region provided at the first part,
a first drain region provided at the second part,
a first gate electrode, and a first gate insulating film provided between the third part and the first gate electrode,
the first semiconductor layer includes a fourth part, a fifth part, and a sixth part provided between the fourth part and the fifth part,
the second semiconductor element includes
a second source region provided at the fourth part,
a second drain region provided at the fifth part, and
a second gate electrode provided on the sixth part.

10. The device according to claim 9, further comprising:
a first drain electrode electrically connected to the first drain region; and
an interconnection electrically connecting the first drain electrode and the second gate electrode.

11. The device according to claim 1, further comprising
an insulating film provided on a center region of the second portion and surrounded by the first semiconductor layer.

12. The device according to claim 1, wherein
the first semiconductor layer includes
a first region provided on the second face, and
a second region provided on the first face and continuous with the first region.

13. The device according to claim 1, further comprising:
a second semiconductor layer provided on the second face, the second semiconductor layer being apart from the first semiconductor layer; and
a third semiconductor element provided at the second semiconductor layer.

14. The device according to claim 1, wherein
the second portion further includes a third face, and
an angle between the third face and the first face is 125 degrees or more and 126 degrees or less.

15. The device according to claim 14, wherein
The third face is a (111) plane of silicon.

16. The device according to claim 14, wherein
the first semiconductor layer further includes a region provided on the third face.

17. The device according to claim 1, wherein
the substrate further includes a third portion,
the third portion has a face parallel to the first face, and
the second portion is provided between the first portion and the third portion.

18. The device according to claim 17, wherein
the third portion has a (100) plane of silicon.

19. The device according to claim 17, wherein
the second portion is provided around the third portion when projected onto a plane parallel to the first face.

20. The device according to claim 1, wherein
the angle is 125.26 degrees.
